(19) United States
(12) Patent Application Publication
(10) Pub. No.: US 2025/0261308 A1
(43) Pub. Date: Aug. 14, 2025

(54) CIRCUIT BOARD, ANTENNA STRUCTURE INCLUDING THE SAME AND IMAGE DISPLAY DEVICE INCLUDING THE SAME

(71) Applicant: DONGWOO FINE-CHEM CO., LTD., Jeollabuk-do (KR)

(72) Inventors: WON HEE LEE, Jeollabuk-do (KR); NA YEON KIM, Jeollabuk-do (KR)

(21) Appl. No.: 19/038,903

(22) Filed: Jan. 28, 2025

(30) Foreign Application Priority Data
Feb. 8, 2024 (KR) 10-2024-0019348

(51) Int. Cl. H05K 1/11; H01Q 1/22; H05K 1/02

(52) U.S. Cl. CPC H05K 1/115; H01Q 1/2283; H05K 1/028; H05K 2201/093; H05K 2201/10098

(57) ABSTRACT

A circuit board includes a core layer including a wiring portion and a ground portion arranged around the wiring portion, a circuit wiring extending on the wiring portion, a first ground pattern arranged around the circuit wiring and spaced apart from the circuit wiring, and a first via structure arranged in the ground portion to penetrate the core layer, The first via structure is not arranged in the wiring portion.

### CROSS-REFERENCE TO RELATED APPLICATION AND CLAIM OF PRIORITY

This application claims the benefit under 35 USC § 119 of Korean Patent Application No. 10-2024-0019348 filed on Feb. 8, 2024 in the Korean Intellectual Property Office, the entire disclosure of which is incorporated herein by reference for all purposes.

### BACKGROUND

### 1. Field

The present invention relates to a circuit board, an antenna structure including the same and an image display device including the same.

### 2. Description of the Related Art

As information technologies have been developed, a wireless communication technology such as Wi-Fi, Bluetooth, etc., is combined with an image display device in the form of, e.g., a smartphone form. In this case, an antenna may be combined with the image display device to provide a communication function.

Recently, as mobile communication technologies have been developed, an antenna for a communication in a high frequency or an ultra-high frequency band is needed in the image display device.

However, when a driving frequency of the antenna increases, a signal loss may also be increased. The signal loss may be further increased as a transmission path becomes longer.

For example, a circuit board including a circuit wiring and a connecting intermediate structure such as a via structure may be used to connect the antenna to a main board of the display device. In this case, antenna performance may be degraded due to signal interference or signal loss caused by bending or deformation of the circuit board.

### SUMMARY

According to an aspect of the present invention, there is provided a circuit board having improved electrical reliability.

According to an aspect of the present invention, there is provided an antenna structure having improved electrical reliability.

According to an aspect of the present invention, there is provided an image display device having improved electrical reliability.

(1) A circuit board includes a core layer including a wiring portion and a ground portion arranged around the wiring portion; a circuit wiring extending on the wiring portion; a first ground pattern arranged around the circuit wiring and spaced apart from the circuit wiring; and a first via structure arranged in the ground portion to penetrate the core layer, wherein the first via structure is not arranged in the wiring portion.

(2) The circuit board according to the above (1), wherein the circuit wiring is not arranged on the ground portion.

(3) The circuit board according to the above (1), wherein the circuit wiring includes a plurality of circuit wirings extending on the wiring portion, and a distance between the ground portion and an outermost circuit wiring among the plurality of circuit wirings is at least three times a line width of the circuit wiring.

(4) The circuit board according to the above (1), wherein the core layer have a first surface and a second surface facing each other, and the circuit wiring and the first ground pattern are arranged on the first surface, wherein the circuit board further comprises a second ground pattern arranged on the second surface.

(5) The circuit board according to the above (4), wherein the first via structure electrically connects the first ground pattern and the second ground pattern.

(6) The circuit board according to the above (1), wherein the first via structure includes a plurality of first via structures, each of which penetrates the core layer in the ground portion.

(7) The circuit board according to the above (6), wherein the plurality of first via structures include outer via structures arranged consecutively along an outermost portion of the circuit board.

(8) The circuit board according to the above (7), wherein the plurality of first via structures further include internal via structures except for the outer via structures.

(9) The circuit board according to the above (8), wherein a distance between adjacent internal via structures is greater than a distance between adjacent outer via structures.

(10) The circuit board according to the above (1), wherein the core layer has a first extension portion, a bent portion connected to the first extension portion, and a second extension portion connected to the bent portion to face the first extension portion.

(11) The circuit board according to the above (1), further including a second via structure penetrating the core layer to be connected to a terminal end portion of the circuit wiring.

(12) The circuit board according to the above (1), further including a protective layer covering the circuit wiring and the first ground pattern.

(13) An antenna structure, including: the above-described circuit board; and an antenna device electrically connected to the circuit board.

(14) The antenna structure according to the above (13), wherein the antenna device includes a radiator and a transmission line connected to the radiator, and the transmission line and the circuit wiring are electrically connected.

(15) An image display device, including: a display panel; and the above-described antenna structure of claim 13.

According to embodiments of the present invention, a core layer may include a bent portion, so that spatial efficiency of a device (e.g., an image display device) including a circuit board may be improved.

According to embodiments of the present invention, the first via structure may be arranged in a ground portion of the circuit board to penetrate the core layer, and may not be arranged in a wiring portion where a circuit wiring extends. Accordingly, unnecessary electric field formation due to bending of the circuit board around the circuit wiring may be suppressed, and signal loss may be prevented. Accordingly, antenna performance substantially the same as or similar to that of a non-bendable circuit board may be implemented.

### BRIEF DESCRIPTION OF THE DRAWINGS

FIGS. 1 and 2 are a schematic plan view and a schematic cross-sectional view, respectively, illustrating a circuit board in accordance with example embodiments.

FIG. 3 is a schematic plan view illustrating a circuit board in accordance with example embodiments.

FIGS. 4 and 5 are a schematic cross-sectional view and a schematic plan view and, respectively, illustrating an antenna structure in accordance with example embodiments.

FIGS. 6 and 7 are a schematic cross-sectional view and a schematic plan view and, respectively, illustrating an image display device in accordance with example embodiments.

FIG. 8 is a schematic plan view illustrating an antenna structure according to Reference Example and Comparative Example.

FIG. 9 is an image showing an electric field generation diagram of antenna structures of Example and Comparative Example.

FIG. 10 is a graph showing an antenna peak gain according to frequencies of antenna structures of Reference Example, Example and Comparative Example.

### DETAILED DESCRIPTION OF THE EMBODIMENTS

According to embodiments of the present invention, a circuit board including a circuit wiring is provided. According to embodiments of the present invention, an antenna structure including the circuit board is provided. According to embodiments of the present invention, an image display device including the circuit board or the antenna structure is provided.

Hereinafter, the present invention will be described in detail with reference to the accompanying drawings. However, those skilled in the art will appreciate that such embodiments described with reference to the accompanying drawings are provided to further understand the spirit of the present invention and do not limit subject matters to be protected as disclosed in the detailed description and appended claims.

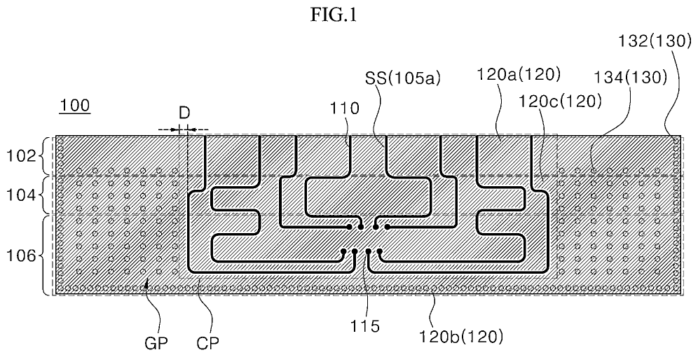

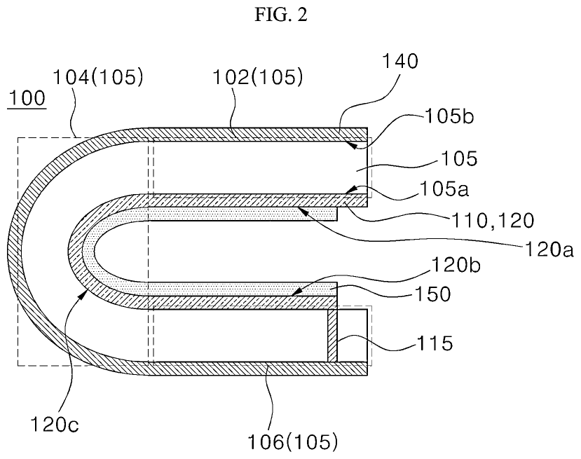

FIGS. 1 and 2 are a schematic plan view and a schematic cross-sectional view, respectively, illustrating a circuit board in accordance with exemplary embodiments. FIG. 2 is a cross-sectional view of a wiring portion CP in a circuit board of FIG. 1.

Referring to FIGS. 1 and 2, a circuit board 100 may include a core layer 105, a circuit wiring 110, a first ground pattern 120, and a first via structure 130.

The core layer 105 may include a wiring portion CP and a ground portion GP disposed around the wiring portion CP.

For example, the wiring portion CP may include a region of the circuit board 100 in which the circuit wiring 110 is disposed. For example, the ground portion GP may indicate a region of the circuit board 100 except for the wiring portion CP.

For example, the ground portion GP may surround the wiring portion CP.

For example, the circuit wiring 110 may not be disposed on the ground portion GP.

The core layer 105 may have a first surface 105a and a second surface 105b facing each other.

In example embodiments, the core layer 105 may include a first extension portion 102, a bent portion 104 connected to the first extension portion 102, and a second extension portion 106 connected to the bent portion 104 to face the first extension portion 102. For example, the first extension portion 102 and the second extension portion 106 may be disposed with the bent portion 104 interposed therebetween.

For example, the bent portion 104 may be provided as a region in which the circuit board 100 is bent. As illustrated in FIG. 2, the circuit board 100 may be bent by the bent portion 104 so that the first surface 105a of the first extension portion 102 and the first surface 105a of the second extension portion 105 may face each other. Accordingly, spatial efficiency of an apparatus (e.g., an image display device) including the circuit board 100 may be improved.

For example, the core layer 105 may include a flexible resin such as a polyimide resin, a modified polyimide (MPI), an epoxy resin, a polyester, a cyclo olefin polymer (COP), a liquid crystal polymer (LCP), or the like. For example, the core layer 105 may include an internal insulating layer included in the circuit board 100.

In example embodiments, the circuit wiring 110 and the first ground pattern 120 may be disposed on the first surface 105a of the core layer 105.

A plurality of the circuit wirings 110 may extend on the first surface 105a of the core layer 105.

In some embodiments, a distance D between the ground portion GP and an outermost circuit wiring among the circuit wirings 110 may be three times or more of a line width of the circuit wiring 110. In an embodiment, the distance D may be 3 to 200 times of the line width of the circuit wiring 110. In the above range, unnecessary electric field formation due to bending of the circuit board 100 around the circuit wiring 110 may be suppressed and an antenna gain may be improved.

The “outermost circuit wiring among the circuit wirings 110” may indicate a circuit wiring closest to the ground portion among the plurality of the circuit wirings 110.

The first ground pattern 120 may be disposed around the circuit wiring 110 to be spaced apart from the circuit wiring 110. Accordingly, noises around the circuit wiring 110 may be suppressed.

For example, the first ground pattern 120 and the circuit wiring 110 may be disposed at the same layer or at the same level.

In some embodiments, the first ground pattern 120 may include a first ground portion 120a disposed on the first surface 105a of the first extension portion 102 and a second ground portion 120b disposed on the first surface 105a of the second extension portion 106.

For example, the first ground pattern 120 may further include a bent ground portion 120c disposed between the first ground portion 120a and the second ground portion 120b and disposed on the first surface 105a of the bent portion 104. The bent ground portion 120c may be bent along a bending profile of the bent portion 104 of the core layer 105.

For example, the first ground portion 120a, the bent ground portion 120c, and the second ground portion 120b may be substantially integrally formed with each other.

In example embodiments, the first via structure 130 may be disposed in the ground portion GP of the circuit board 100 to penetrate the core layer 105, and may not be disposed in the wiring portion CP. Accordingly, unnecessary electric field formation due to bending of the circuit board 100 around the circuit wiring 110 may be suppressed while preventing signal loss. Thus, antenna performance substantially the same as or similar to that of a non-bent circuit board 100 may be implemented.

In a comparative example in which the first via structure 130 is disposed in the wiring portion CP, interference capacitance according to bending of the circuit board 100 may occur around the circuit wiring 110 to degrade the antenna gain.

In example embodiments, a plurality of the first via structures 130 may be arranged in the ground portion GP.

In some embodiments, the plurality of the first via structures 130 may include outer via structures 132 consecutively arranged along an outermost portion of the circuit board 100.

In some embodiments, the plurality of the first via structures 130 may include internal via structures 134 except for the outer via structures 132.

In some embodiments, a distance between neighboring internal via structures 134 may be greater than a distance between neighboring outer via structures 132. Accordingly, process efficiency may be improved while further shielding noises, and electrical reliability of the circuit board 100 may be improved.

In an embodiment, the distance between the neighboring outer via structures 132 may be substantially uniform.

In an embodiment, the distance between the neighboring internal via structures 134 may be uniform.

In some embodiments, the circuit board 100 may further include a second ground pattern 140 disposed on the second surface 105b of the core layer 105. Accordingly, electric field concentration of a signal transferred to the circuit wiring 110 may be improved while shielding noises.

For example, the first via structure 130 may penetrate the core layer 105 in the ground portion GP to electrically connect the first ground pattern 120 and the second ground pattern 140. Accordingly, signal compatibility of the first surface 105a and the second surface 105b of the core layer 105 may be improved, and signal loss may be suppressed.

For example, the first via structure 130 may overlap each of the first ground pattern 120 and the second ground pattern 140 in a plan view.

For example, the first via structure 130, the first ground pattern 120, and the second ground pattern 140 may be formed as a substantially integral or single unitary member. For example, after forming a via hole penetrating the core layer 105 in the ground portion GP, the first via structure 130, the first ground pattern 120, and the second ground pattern 140 may be integrally formed by forming and patterning a metal or alloy layer.

In some embodiments, the circuit board 100 may further include a protective layer 150 covering the circuit wiring 110 and the first ground pattern 120. Accordingly, impact resistance of the circuit wiring 110 and driving stability of the circuit board 100 may be improved.

For example, a coverlay film covering the circuit wirings 110 may be provided as the protective layer 150.

For example, the protective layer 150 may include substantially the same type of material as that of the core layer 105.

In an embodiment, the protective layer 150 may include a cover window. The cover window may include, e.g., an ultra-thin glass (UTG) or a transparent resin film.

Accordingly, an external impact applied to the circuit wiring 110 may be reduced or buffered.

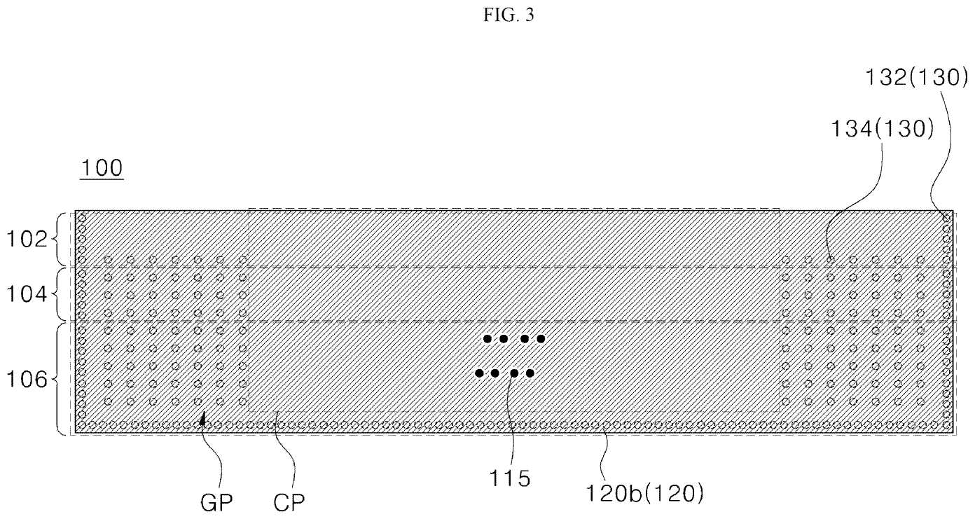

FIG. 3 is a schematic plan view illustrating a circuit board in accordance with exemplary embodiments. FIG. 3 is a plan view of the core layer 105 observed in a direction of the second surface 105b.

Although FIGS. 1 and 3 illustrates the circuit board 100 in a non-bent state for convenience of descriptions, the circuit board 100 of the present application is to be interpreted in a bent shape by the bent portion 104 as illustrated in FIG. 2.

Referring to FIG. 3, the circuit board 100 may further include a second via structure 115 penetrating the core layer 105 and connected to a terminal end portion of the circuit wiring 110. A signal transferred to the circuit wiring 110 on the first surface 105a may be transferred to the second surface 105b through the second via structure 115.

For example, the second via structure 115 may be disposed in the wiring portion CP.

For example, a signal may be transmitted and received from a control device connected to the second surface 105a through the second via structure 115.

For example, the circuit wiring 110 and the second via structure 115 may be formed as a substantially single or unitary member. For example, after forming a via hole penetrating the core layer 105, the circuit wiring 110 and the second via structure 115 may be integrally formed by forming and patterning a metal or alloy layer.

In some embodiments, a separation space SS in the form of a trench may be formed between the circuit wiring 110 and the first ground pattern 120. Accordingly, loss of the signal transmitted through the circuit wiring 110 may be suppressed, and noises may be shielded.

For example, a shape of the spacing space SS may be changed by adjusting the patterning shape of the first ground pattern 120.

For example, the separation space SS may also be formed between the second via structure 115 and the first ground pattern 120 and/or between the second via structure 115 and the second ground pattern 140. For example, the second via structure 115 and the second ground pattern 140 may be spaced apart by the separation space SS.

In some embodiments, the first ground pattern 120 may be entirely disposed on the first surface 105a of the core layer 105 in a region except for the circuit wiring 110, the second via structure 115, and the spacing space SS.

In some embodiments, the second ground pattern 140 may be entirely disposed on the second surface 105b of the core layer 105 in a region except for the second via structure 115 and the separation space SS.

The circuit wiring 110, the first ground pattern 120, the second ground pattern 140, the first via structure 130, and/or the second via structure 115 may include silver (Ag), gold (Au), copper (Cu), aluminum (Al), platinum (Pt), palladium (Pd), chromium (Cr), titanium (Ti), tungsten (W), niobium (Nb), tantalum (Ta), vanadium (V), iron (Fe), manganese (Co), cobalt (Ni), zinc (Zn), tin (Sn), molybdenum (Mo), calcium (Ca), or an alloy containing at least one thereof. These may be used alone or in a combination of two or more therefrom.

In an embodiment, the circuit wiring 110, the first ground pattern 120, the second ground pattern 140, the first via structure 130, and/or the second via structure 115 may include silver (Ag) or a silver alloy (e.g., a silver-palladium-copper (APC) alloy), or copper or a copper alloy (e.g., a copper-calcium (CuCa) alloy) to implement a low resistance and a fine line width patterning.

For example, circuit wiring 110, first ground pattern 120, second ground pattern 140, the first via structure 130, and/or second via structure 115 may be formed in a solid pattern to reduce a feeding resistance and prevent a signal loss.

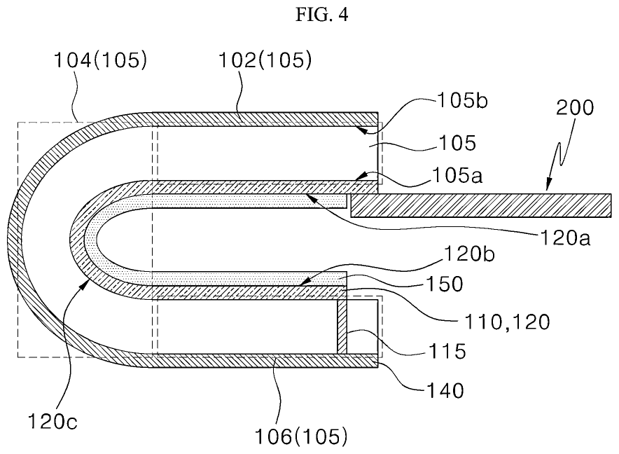

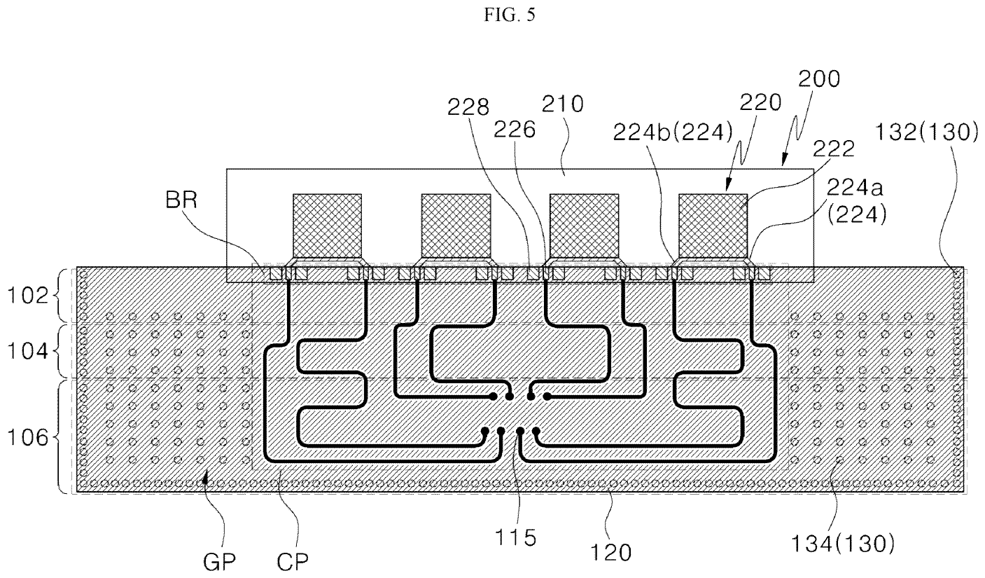

FIGS. 4 and 5 are a schematic cross-sectional view and a schematic plan view and, respectively, illustrating an antenna structure in accordance with exemplary embodiments.

Referring to FIGS. 4 and 5, the antenna structure may include the above-described circuit board 100 and an antenna device 200 electrically connected to the circuit board 100.

For example, the antenna device 200 may include a dielectric layer 210 and an antenna unit 220 disposed on the dielectric layer 210.

The dielectric layer 210 may include a transparent resin material. For example, the dielectric layer 210 may include a polyester-based resin such as polyethylene terephthalate, polyethylene isophthalate, polyethylene naphthalate and polybutylene terephthalate; a cellulose-based resin such as diacetyl cellulose and triacetyl cellulose; a polycarbonate-based resin; an acrylic resin such as polymethyl (meth)acrylate and polyethyl (meth)acrylate; a styrene-based resin such as polystyrene and an acrylonitrile-styrene copolymer; a polyolefin-based resin such as polyethylene, polypropylene, a cycloolefin or polyolefin having a norbornene structure and an ethylene-propylene copolymer; a vinyl chloride-based resin; an amide-based resin such as nylon and an aromatic polyamide; an imide-based resin; a polyethersulfone-based resin; a sulfone-based resin; a polyether ether ketone-based resin; a polyphenylene sulfide resin; a vinyl alcohol-based resin; a vinylidene chloride-based resin; a vinyl butyral-based resin; an allylate-based resin; a polyoxymethylene-based resin; an epoxy-based resin; a urethane or acrylic urethane-based resin; a silicone-based resin, etc. These may be used alone or in a combination of two or more therefrom.

In some embodiments, an adhesive film such as an optically clear adhesive (OCA) or an optically clear resin (OCR) may be included in the dielectric layer 210.

In some embodiments, the dielectric layer 210 may include an inorganic insulating material such as silicon oxide, silicon nitride, silicon oxynitride, glass, etc.

In an embodiment, the dielectric layer 210 may be provided as a substantially single layer.

In an embodiment, the dielectric layer 210 may include a multi-layered structure of at least two or more layers. For example, the dielectric layer 210 may include a substrate layer and a dielectric layer, and may include an adhesive layer between the substrate layer and the dielectric layer.

An impedance or an inductance of the antenna unit 220 may be formed by the dielectric layer 210 so that a frequency band in which the antenna structure may be driven or operated may be adjusted. In some embodiments, a dielectric constant of the dielectric layer 210 may be adjusted in a range from about 1.5 to about 12. When the dielectric constant is greater than about 12, a driving frequency may be excessively reduced and driving in a high frequency band may not be implemented.

In an embodiment, an antenna ground (not illustrated) may be disposed under a bottom surface of the dielectric layer 210.

In an embodiment, a conductive member of an image display device or a display panel to which the antenna structure is applied may serve as the antenna ground.

For example, the conductive member may include electrodes or wirings such as a gate electrode, a source/drain electrode, a pixel electrode, a common electrode, a data line, a scan line, etc., included in a thin film transistor array panel.

In an embodiment, a metallic member such as an SUS plate, a sensor member such as a digitizer, and a heat dissipation sheet disposed at a rear surface of the image display device may serve as the antenna ground.

In example embodiments, the antenna unit 220 may include a radiator 222 and a transmission line 224 connected to the radiator 222. The transmission line 224 may extend from the radiator 222.

For example, the radiator 222 has a polygonal plate shape, the transmission line 224 may have a width smaller than that of the radiator 222, and may be connected to one end portion or one side of the radiator 222. The radiator 222 and the transmission line 224 may be formed as a single member integrally connected to each other.

A target resonance frequency of the antenna device 200 may be adjusted according to a shape/size of the radiator 222. In a non-limiting embodiment, the radiator 222 may be designed to be radiable in a high frequency/ultra-high frequency band of 3G, 4G, 5G or more. For example, a radiation band in a frequency band of 0.5 GHz or more, 1 GHz or more, 10 GHz or more, 20 GHz or more, 30 GHz or more, or 40 GHz or more may be implemented through the radiator 222.

For example, the radiator 222 may be provided as a high frequency band radiator of the antenna unit 220. In an embodiment, the resonance frequency of the radiator 222 may be about 28 GHz or more.

The transmission line may include a first transmission line 224a and a second transmission line 224b connected to the radiator 222 and facing each other. Accordingly, two polarization directions (dual polarization) may be implemented in a single radiator.

In some embodiments, each of the first transmission line 224a and the second transmission line 224b may be connected to both lateral portions of a lower surface of the radiator 222 (e.g., both vertices of the lower surface of the radiator 222).

The first transmission line 224a and the second transmission line 224b may extend from the radiator 222 in different directions. Accordingly, dual polarization properties may be implemented from one radiator 222.

In some embodiments, an angle formed by extension directions of the first transmission line 224a and the second transmission line 224b may be about 90°. For example, the extension directions of the first transmission line 224a and the second transmission line 224b may be orthogonal to each other. In an embodiment, the first transmission line 224a and the second transmission line 224b may extend toward a center of the radiator.

Accordingly, feeding of the radiator 222 in two directions that are substantially orthogonal to each other may be performed through the first transmission line 224a and the second transmission line 224b. For example, vertical radiation and horizontal radiation from the radiator 222 may be implemented together.

In some embodiments, the first transmission line 224a and the second transmission line 224b may be arranged to be symmetrical to each other. For example, the first transmission line 224a and the second transmission line 224b may be arranged to be symmetrical to each other with respect to a central line passing through a center of the radiator 222. Thus, signal intensity in two polarization directions may become substantially uniform.

In some embodiments, a signal pad 226 may be disposed at an end portion of the transmission line 224. The signal pad 226 may be a single member substantially integral with the transmission line 224. In this case, the end portion of the transmission line 224 may serve as the signal pad 226.

For example, the radiator 222 and the signal pad 226 may be electrically connected through the transmission line 224.

The circuit board 100 and the antenna unit 220 may be electrically connected through the signal pad 226. Accordingly, signal transmission and reception between the antenna driving integrated circuit (IC) chip and the radiator 222 of the circuit board 100 may be implemented.

In some embodiments, the antenna unit 220 may further include a ground pad 228 spaced apart from the signal pad 226 around the signal pad 226. The ground pad 228 may be electrically and physically separated from the transmission line 224 and the signal pad 226. In an embodiment, a pair of the ground pads 228 may be disposed to face each other with the signal pad 226 interposed therebetween. Accordingly, generation of noise of the signal transmitted through the signal pad 226 may be reduced.

For example, the signal pad 226 and the ground pad 228 may be disposed in a bonding region BR in which the antenna device 200 and the circuit board 100 are bonded. For example, bonding stability of the antenna device 200 and the circuit board 100 in the bonding region BR may be improved by the ground pad 228.

In an embodiment, the signal pad 226 and the ground pad 228 may have a solid structure. Accordingly, an increase in resistance due to the bonding at connected portions of the antenna device 200 and the circuit board 100 may be suppressed, and feeding efficiency may be increased.

In some embodiments, the circuit wiring 110 and the antenna device 200 may be connected on the first extension portion 102 of the circuit board 100. For example, the transmission line 224 and the circuit wiring 110 may be electrically connected.

For example, a conductive bonding structure such as an ACF may be attached to an end portion of the signal pad 226 or the transmission line 224 in the bonding region BR. For example, a portion of the protective layer 150 (e.g., a coverlay film) may be removed to expose one end portion of the circuit wiring 110 disposed on the first surface 105a of the first extension portion 102. The exposed one end portion may be disposed on the conductive bonding structure, and the circuit board 100 and the antenna device 200 may be connected to each other by a heat treatment and a pressurizing process.

Accordingly, feeding and signal transfer between an device including the antenna structure and the antenna device 200 may be implemented.

For example, one end portion of the circuit wiring 110 may be connected to the antenna device 200, and the other end portion may be connected to the second via structure 115.

The antenna unit 220 may include silver (Ag), gold (Au), copper (Cu), aluminum (Al), platinum (Pt), palladium (Pd), chromium (Cr), titanium (Ti), tungsten (W), niobium (Nb), tantalum (Ta), vanadium (V), iron (Fe), manganese (Mn), cobalt (Co), nickel (Ni), zinc (Zn), tin (Sn), molybdenum (Mo), calcium (Ca) or an alloy containing at least one of the metals. These may be used alone or in a combination of two or more therefrom.

In an embodiment, the antenna unit 220 may include silver (Ag) or a silver alloy (e.g., silver-palladium-copper (APC)), or copper (Cu) or a copper alloy (e.g., a copper-calcium (CuCa)) to implement a low resistance and a fine line width pattern.

In some embodiments, the antenna unit 220 may include a transparent conductive oxide such as indium tin oxide (ITO), indium zinc oxide (IZO), zinc oxide (ZnOx), indium zinc tin oxide (IZTO), etc.

In some embodiments, the antenna unit 220 may include a stacked structure of a transparent conductive oxide layer and a metal layer. For example, the antenna unit may include a double-layered structure of a transparent conductive oxide layer-metal layer, or a triple-layered structure of a transparent conductive oxide layer-metal layer-transparent conductive oxide layer. In this case, flexible property may be improved by the metal layer, and a signal transmission rate may also be improved by a low resistance of the metal layer. Corrosive resistance and transparency may be improved by the transparent conductive oxide layer.

The antenna unit 220 may include a blackened portion, so that a reflectance at a surface of the antenna unit 220 may be decreased to suppress a visual recognition of the antenna unit due to a light reflectance.

In an embodiment, a surface of the metal layer included in the antenna unit 220 may be converted into a metal oxide or a metal sulfide to form a blackened layer. In an embodiment, a blackened layer such as a black material coating layer or a plating layer may be formed on the antenna unit 220 or the metal layer. The black material or plating layer may include silicon, carbon, copper, molybdenum, tin, chromium, molybdenum, nickel, cobalt, or an oxide, sulfide or alloy containing at least one therefrom.

A composition and a thickness of the blackened layer may be adjusted in consideration of a reflectance reduction effect and an antenna radiation property.

In some embodiments, the radiator 222 may include a mesh structure, and at least a portion of the transmission line 224 and the signal pad 226 may include a solid structure. In an embodiment, at least a portion of the radiator 222 may be formed in a mesh structure, and a remaining portion may be formed in a solid structure.

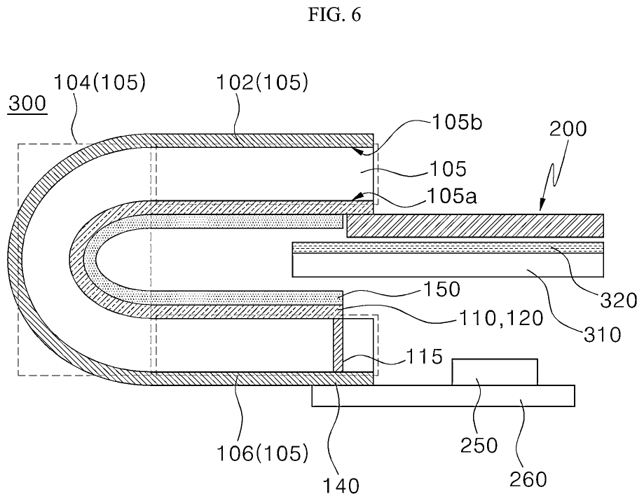

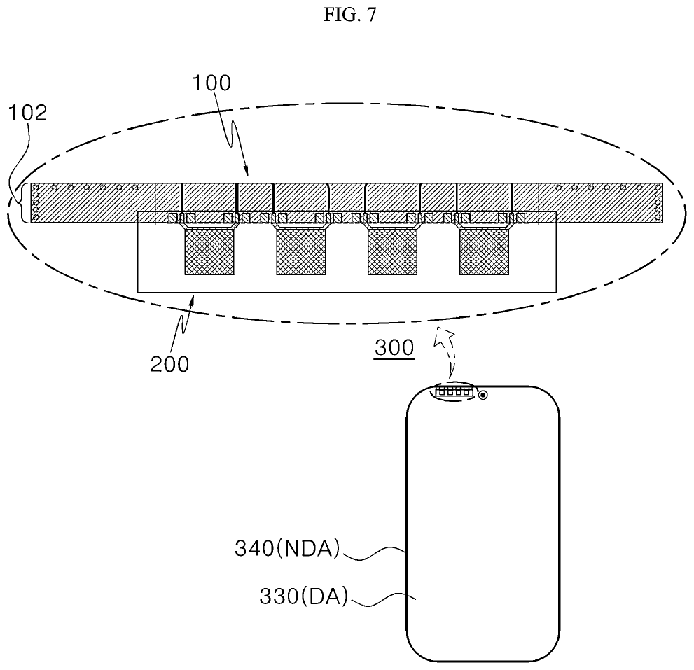

FIGS. 6 and 7 are a schematic cross-sectional view and a schematic plan view and, respectively, illustrating an image display device in accordance with exemplary embodiments.

A front portion of the image display device 300 may include a display area DA 330 and a non-display area NDA 340. The non-display area 340 may correspond to, e.g., a light-shielding portion or a bezel portion of the image display device 300.

The antenna device 200 according to example embodiments may be disposed toward a front surface of the image display device 300. For example, the antenna device 200 may be disposed on the display panel 310.

In some embodiments, the antenna device 200 may be attached to the display panel 310 in the form of a film.

In an embodiment, the antenna device 200 may be formed over the display area 330 and the non-display area 340 of the image display device 300. In an embodiment, the radiator 222 may be at least partially disposed in the display area 330.

As described above, the transmission line 224, the signal pad 226 and the ground pad 228 may overlap the non-display area 340 in a thickness direction. For example, a portion of the antenna unit 220 having a solid structure may overlap the non-display area 340.

In some embodiments, the antenna device 200 may be located in a central portion of one side of the image display device 300. Accordingly, deterioration of a radiation performance from either side may be prevented.

The antenna device 200 may be fed or driven through the circuit board 100.

An antenna driving integrated circuit (IC) chip 250 may be mounted on the circuit board 100. As illustrated in FIG. 6, an intermediate circuit board 260 such as a rigid printed circuit board may be disposed between the circuit board 100 and the antenna driving IC chip 250. In an embodiment, the antenna driving IC chip 250 may be directly mounted on the circuit board 100.

Referring to FIG. 6, the image display device 300 may include a display panel 310 and the above-described antenna device 200 disposed on the display panel 310.

In example embodiments, an optical layer 320 may be further included on the display panel 310. For example, the optical layer 320 may be a polarizing layer including a polarizer or a polarizing plate.

The circuit board 100 (e.g., a flexible printed circuit board) may be bent along a side bending profile of the display panel 310 and disposed at a rear side of the image display device 300, and may extend toward the intermediate circuit board 260 (e.g., a main board) on which the antenna driving IC chip 250 is mounted.

The circuit board 100 and the intermediate circuit board 260 may be bonded or interconnected through a connector, so that feeding and antenna driving control to the antenna device 200 may be performed by the antenna driving IC chip 250.

In some embodiments, the antenna device 200 may be disposed on the display panel 310, and the circuit board 100 may be bent using the bent portion 104 to extend below the display panel 310. Accordingly, spatial efficiency of the image display device 300 may be improved. Further, generation of an unnecessary electric field due to the bending may be suppressed and an antenna gain may be improved by the above-described construction of the circuit board 100.

For example, the circuit board 100 and the antenna device 200 may be connected on the first extension portion 102, and the circuit board 100 and the antenna driving IC chip 250 may be connected on the second extension portion 106. Accordingly, feeding and signaling may be implemented from the antenna driving IC chip 250 to the antenna unit 220.

Hereinafter, embodiments are presented to enhance understanding of the present invention, but these embodiments illustrate the present invention and do not limit the scope of the attached claims, and it is clear to those skilled in the art that various changes and modifications to the embodiments are possible within the scope of the present invention and technical ideas. These modifications and modifications fall within the scope of the attached claims.

### Reference Example (Non-Bent)

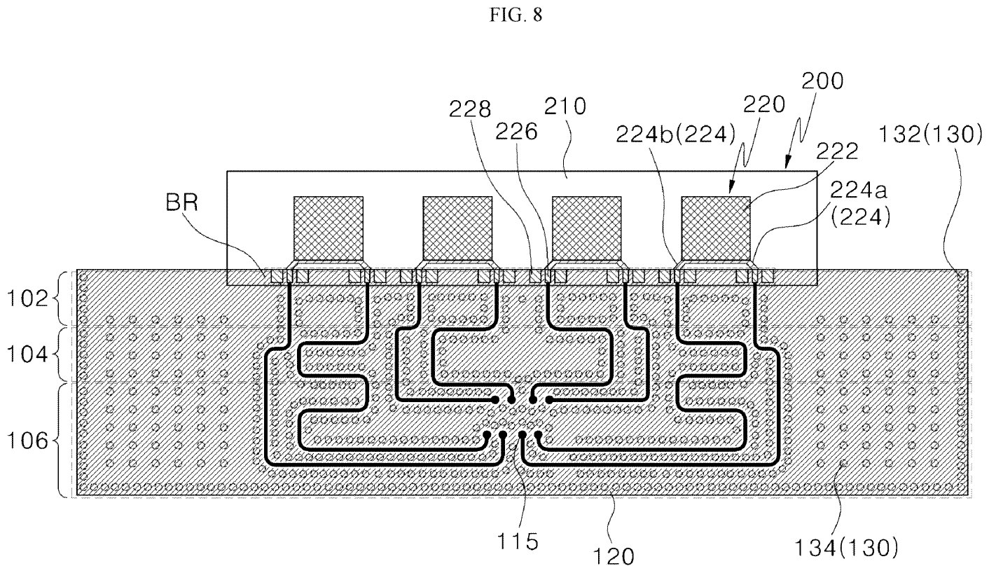

Conductive lines containing copper (Cu) and via structures penetrating the COP dielectric layer were patterned on the COP dielectric layer as illustrated in FIG. 8 to obtain an antenna structure.

A line width of the conductive lines was 2 μm and the thickness was 0.5 μm.

A target resonance frequency of the antenna unit was adjusted to about 28 GHz band.

### Example

The antenna structure manufactured by the same method as that in Reference Example was used as a preliminary antenna structure, except that the first via structure was not formed in the wiring portion as illustrated in FIG. 5.

The antenna structure was manufactured by bending the circuit board of the preliminary antenna structure by the bent portion.

### Comparative Example

An antenna structure was manufactured by the same method as that in Example, except that the antenna structure (the first via structure was formed in the wiring portion) manufactured by the same method as that in Reference Example was used as a preliminary antenna structure.

### Experimental Example

Electric field formations and antenna peaks gain according to frequencies of the antenna structures by Example and Comparative Example were measured using an HFSS simulator (Ansys Co., Ltd.).

In Example and Comparative Example, a feeding was performed on four of eight circuit wirings. The circuit wirings to which the feeding was performed and the circuit wirings to which the feeding was not performed were alternately arranged.

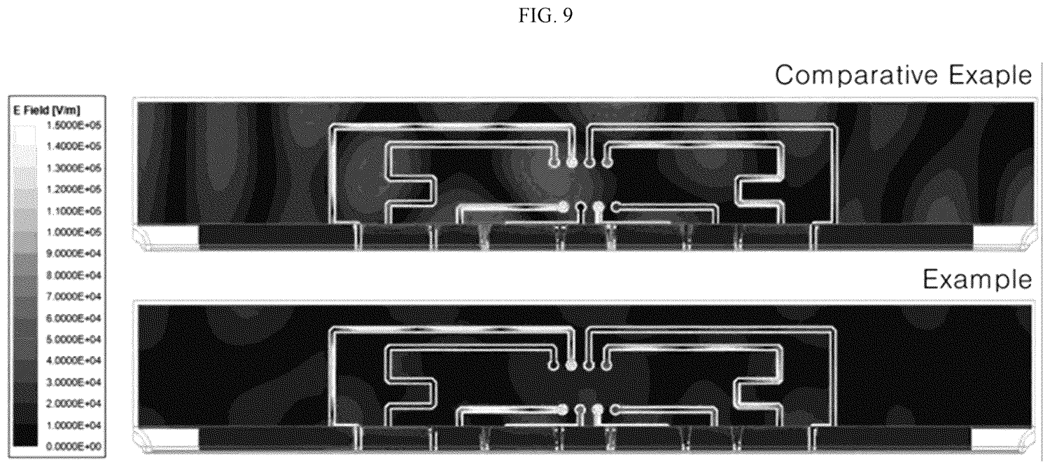

FIG. 9 is an image illustrating an electric field generation diagram of antenna structures of Example and Comparative Example.

Referring to FIG. 9, in Example, an unnecessary electric field formation around the circuit wiring was suppressed compared to that from Comparative Example.

Specifically, in Example, the electric field was concentrated in the circuit wiring and the formation of the electric field in the first ground pattern was suppressed. However, in Comparative Example, the unnecessary electric field was formed in the first ground pattern, resulting in a reduction of antenna gain.

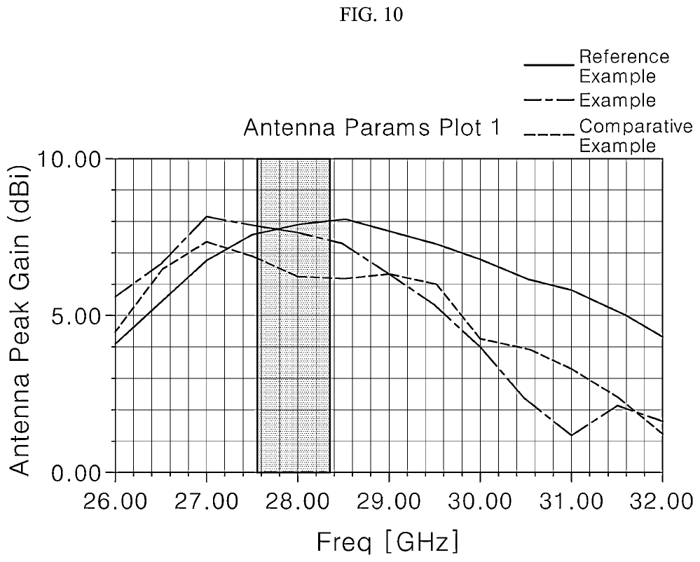

FIG. 10 is a graph showing an antenna peak gain according to frequencies of antenna structures of Reference Example, Example and Comparative Example.

Referring to FIG. 10, in Example where the first via structure was not disposed in the wiring portion, the antenna peak gain in a target frequency band (square box region) was improved compared to that from Comparative Example.

In Comparative Example, the unnecessary electric field was formed according to bending of the circuit board, and the antenna peak gain was lowered compared to that when the circuit board was not bent.

In Example where the first via structure was disposed on the ground portion and was not disposed in the wiring portion, the antenna peak gain substantially similar to that from Reference Example in which the circuit board is not bent was measured even when bending the circuit board.

What is claimed is:

1. A circuit board comprising:
a core layer comprising a wiring portion and a ground portion arranged around the wiring portion;
a circuit wiring extending on the wiring portion;
a first ground pattern arranged around the circuit wiring and spaced apart from the circuit wiring; and
a first via structure arranged in the ground portion to penetrate the core layer, wherein the first via structure is not arranged in the wiring portion.

2. The circuit board according to claim 1, wherein the circuit wiring is not arranged on the ground portion.

3. The circuit board according to claim 1, wherein the circuit wiring comprises a plurality of circuit wirings extending on the wiring portion, and
a distance between the ground portion and an outermost circuit wiring among the plurality of circuit wirings is at least three times a line width of the circuit wiring.

4. The circuit board according to claim 1, wherein the core layer have a first surface and a second surface facing each other, and the circuit wiring and the first ground pattern are arranged on the first surface,
wherein the circuit board further comprises a second ground pattern arranged on the second surface.

5. The circuit board according to claim 4, wherein the first via structure electrically connects the first ground pattern and the second ground pattern.

6. The circuit board according to claim 1, wherein the first via structure comprises a plurality of first via structures, each of which penetrates the core layer in the ground portion.

7. The circuit board according to claim 6, wherein the plurality of first via structures comprise outer via structures arranged consecutively along an outermost portion of the circuit board.

8. The circuit board according to claim 7, wherein the plurality of first via structures further comprise internal via structures except for the outer via structures.

9. The circuit board according to claim 8, wherein a distance between adjacent internal via structures is greater than a distance between adjacent outer via structures.

10. The circuit board according to claim 1, wherein the core layer has a first extension portion, a bent portion connected to the first extension portion, and a second extension portion connected to the bent portion to face the first extension portion.

11. The circuit board according to claim 1, further comprising a second via structure penetrating the core layer to be connected to a terminal end portion of the circuit wiring.

12. The circuit board according to claim 1, further comprising a protective layer covering the circuit wiring and the first ground pattern.

13. An antenna structure comprising:
the circuit board according to claim 1; and
an antenna device electrically connected to the circuit board.

14. The antenna structure according to claim 13, wherein the antenna device comprises a radiator and a transmission line connected to the radiator, and the transmission line and the circuit wiring are electrically connected.

15. An image display device comprising:
a display panel; and
the antenna structure of claim 13 on the display panel.
